(19) United States
(12) Patent Application Publication
(10) Pub. No.: US 2026/0149260 A1
(43) Pub. Date: May 28, 2026

(54) DAMPING OSCILLATIONS IN SOLID-STATE CIRCUIT INTERRUPT DEVICES

(71) Applicant: Schneider Electric USA, Inc., Andover, MA (US)

(72) Inventors: Gregorio Valdovinos FIERRO, Tlajomulco (MX); Gabriela Villa RUIZ, Monterrey (MX); Gustavo García RIVERO, Apodaca (MX)

(73) Assignee: Schneider Electric USA, Inc., Andover, MA (US)

(21) Appl. No.: 18/961,387

(22) Filed: Nov. 26, 2024

(51) Int. Cl. H02H 3/10; H03K 17/16; H03K 17/284

(52) U.S. Cl. CPC H02H 3/10; H03K 17/165; H03K 17/284; H03K 2217/0027

(57) ABSTRACT

Systems/methods for controlling current flow in a solid-state circuit breaker uses a MOSFET based semiconductor switch. Unlike conventional semiconductor switches that use a discrete damping resistor to suppress current oscillations, the semiconductor switch herein uses an additional transistor to induce a damping resistance. The use of a transistor to create a damping resistance allows the damping resistance to be deployed temporarily, on an as-needed basis. In some embodiments, the damping resistance is created by causing a voltage differential to arise across the current flow terminals of the additional transistor. This may be achieved by turning on the additional transistor sequentially, after a predefined time delay, rather than simultaneously with the main transistor of the semiconductor switch. The voltage differential may then be removed to remove the damping resistance when the damping resistance is no longer needed.

### TECHNICAL FIELD

The present disclosure relates to solid-state circuit interrupt devices, and particularly to systems and methods for controlling current flow in such solid-state circuit interrupt devices using a linear slope gate driver as well as a semiconductor switch having a damping resistance therein.

### BACKGROUND

Solid-state circuit breakers (SSCB) and other solid-state circuit interrupt devices use a semiconductor switch to control current flow to a load. A semiconductor switch provides several advantages over mechanical trip units that are used in traditional thermomechanical circuit breakers. For one thing, a semiconductor switch has no moving parts, which eliminates or greatly reduces the risk of arc flash and similar hazards due to electrical arcing that can occur with a mechanical trip unit. This makes solid-state circuit breakers particularly suitable for use in high voltage and current applications, such as electric vehicles, most military defense and aerospace applications, and many industrial equipment applications. A semiconductor switch can also open and close extremely fast, within a few microseconds in some cases, which allows solid-state circuit breakers to interrupt current flow much more quickly compared to a mechanical trip unit.

However, while a number of advances have been made in the field of solid-state circuit interrupt devices, it will be appreciated that improvements are continually needed.

### SUMMARY

Embodiments of the present disclosure relate to systems and methods for controlling current flow in a solid-state circuit interrupt device using a linear slope gate driver as well as a semiconductor switch having a damping resistance therein.

In some embodiments, the linear slope gate driver is a MOSFET based gate driver that can be configured to generate a gate voltage signal having a constant or linear slope. The linear slope of the gate voltage signal, when applied to a semiconductor switch, causes a substantially constant current to flow in either direction through the semiconductor switch. The constant current flow may then be used to power on one or more loads in a manner that is easier to control and manage compared to a variable current flow. In some embodiments, the gate driver generates the linear slope gate voltage signal by using a plurality of discrete voltage steps that resemble a set of stairs to simulate or approximate a straight line slope. This allows the slope of the voltage signal to be defined by selecting the horizontal and vertical increments of the voltage steps.

In some embodiments, the semiconductor switch is also a MOSFET based semiconductor switch. However, unlike some conventional semiconductor switches that use a discrete damping resistor to suppress current oscillations, the semiconductor switch herein uses an additional transistor to induce a damping resistance. The use of a transistor to create a damping resistance allows the damping resistance to be deployed temporarily on an as-needed basis. In some embodiments, the damping resistance is created by causing a voltage differential to arise across the current flow terminals of the additional transistor. This may be achieved by turning on the additional transistor sequentially, after a predefined time delay, rather than simultaneously with the main transistor of the semiconductor switch. The voltage differential may then be removed to remove the damping resistance when the damping resistance is no longer needed.

In general, in one aspect, embodiments of the present disclosure relate to a solid-state circuit interrupt device. The solid-state circuit interrupt device comprises, among other things, a semiconductor switch operable to control current flow therethrough, and a gate driver electrically coupled to the semiconductor switch and configured to apply a gate voltage signal to the semiconductor switch. The solid-state circuit interrupt device further comprises a microcontroller electrically coupled to the gate driver and configured to control the gate driver. The microcontroller is configured to control the gate driver by obtaining a damping resistance for the semiconductor switch, and controlling the gate driver to apply the gate voltage signal to the semiconductor switch to induce the damping resistance in the semiconductor switch. The damping resistance is induced in the semiconductor switch while the gate voltage signal is applied to the semiconductor switch.

In general, in another aspect, embodiments of the present disclosure relate to a method of controlling current flow in a solid-state circuit interrupt device. The method comprises, among other things, providing a semiconductor switch in the solid-state circuit interrupt device, the semiconductor switch operable to control current flow therethrough, and coupling a gate driver electrically to the semiconductor switch in the solid-state circuit interrupt device, the gate driver configured to apply a gate voltage signal to the semiconductor switch. The method also comprises coupling a microcontroller electrically to the gate driver in the solid-state circuit interrupt device, the microcontroller configured to control the gate driver. The method further comprises configuring the microcontroller to obtain a damping resistance for the semiconductor switch, and control the gate driver to apply the gate voltage signal to the semiconductor switch to induce the damping resistance in the semiconductor switch. The damping resistance is induced in the semiconductor switch while the gate voltage signal is applied to the semiconductor switch.

In general, in yet another aspect, embodiments of the present disclosure relate to a non-transitory computer-readable medium having computer-readable instructions stored thereon for controlling current flow in a solid-state circuit interrupt device. The computer-readable instructions, when executed by a controller in the solid-state circuit interrupt device, cause the controller to obtain a damping resistance for a semiconductor switch of the solid-state circuit interrupt device, and control a gate driver of the solid-state circuit interrupt device to apply a gate voltage signal to the semiconductor switch to induce the damping resistance in the semiconductor switch. The damping resistance is induced in the semiconductor switch while the gate voltage signal is applied to the semiconductor switch.

In accordance with any one or more of the foregoing embodiments, the microcontroller is further configured to obtain the damping resistance by calculating a critically damped resistance value for the damping resistance.

In accordance with any one or more of the foregoing embodiments, the semiconductor switch comprises at least two transistors connected in series, and the gate voltage signal is applied to each transistor.

In accordance with any one or more of the foregoing embodiments, the gate voltage signal applied to one of the transistors is a time shifted version of the gate voltage signal applied to another one of the transistors.

In accordance with any one or more of the foregoing embodiments, the time shifted version of the gate voltage signal is shifted in time by a predefined shift time relative to the gate voltage signal that is applied to the another one of the transistors.

In accordance with any one or more of the foregoing embodiments, the predefined shift time is implemented by: the microcontroller, or a resistor-capacitor network connected to the semiconductor switch.

In accordance with any one or more of the foregoing embodiments, the damping resistance is phased out to a characteristic resistance across the drain and source terminals of a transistor in the semiconductor switch when an output voltage at the semiconductor switch has reached a desired voltage.

### BRIEF DESCRIPTION OF THE DRAWINGS

FIG. 1 illustrates an example electric vehicle having a solid-state circuit breaker in accordance with embodiments of the present disclosure;

FIG. 2 illustrates an example power distribution system having a solid-state circuit breaker in accordance with embodiments of the present disclosure;

FIGS. 3A-3B illustrate example linear slope gate voltage signals for a solid-state circuit breaker in accordance with embodiments of the present disclosure;

FIGS. 4A-4C illustrate an example linear slope gate driver for a solid-state circuit breaker in accordance with embodiments of the present disclosure;

FIG. 5 illustrates an example method of generating a linear slope gate voltage signal for a solid-state circuit breaker in accordance with embodiments of the disclosure;

FIGS. 6A-6B illustrate an example semiconductor switch for a solid-state circuit breaker in accordance with embodiments of the present disclosure;

FIGS. 7A-7B illustrate an alternative semiconductor switch for a solid-state circuit breaker in accordance with embodiments of the present disclosure;

FIG. 8 illustrates an example method of producing a damping resistance for a solid-state circuit breaker in accordance with embodiments of the present disclosure;

FIG. 9 illustrates another alternative semiconductor switch for a solid-state circuit breaker in accordance with embodiments of the present disclosure;

FIG. 10 illustrates an example computing system that may be used for a solid-state circuit breaker in accordance with embodiments of the present disclosure; and

FIG. 11 illustrates an example storage system that may be used for a solid-state circuit breaker in accordance with embodiments of the present disclosure.

### DETAILED DESCRIPTION

This description and the accompanying drawings illustrate example embodiments of the present disclosure and should not be taken as limiting, with the claims defining the scope of the present disclosure, including equivalents. Various mechanical, compositional, structural, electrical, and operational changes may be made without departing from the scope of this description and the claims, including equivalents. In some instances, well-known structures and techniques have not been shown or described in detail so as not to obscure the disclosure. Further, elements and their associated aspects that are described in detail with reference to one embodiment may, whenever practical, be included in other embodiments in which they are not specifically shown or described. For example, if an element is described in detail with reference to one embodiment and is not described with reference to a second embodiment, the element may nevertheless be claimed as included in the second embodiment.

As alluded to above, solid-state circuit breakers are particularly suitable for use in high voltage and current applications, such as electric vehicles, most military defense and aerospace application, and many industrial equipment applications. However, embodiments of the present disclosure are not limited to high voltage and current applications, but may also include solid-state circuit breakers used in low voltage and current applications as well as medium voltage and current applications.

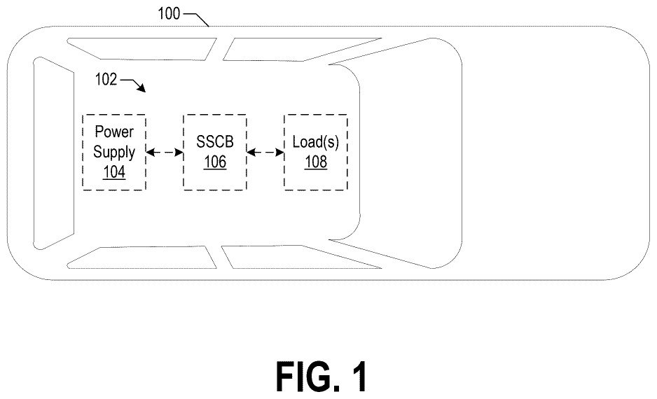

Referring now to FIG. 1, a conceptual diagram is shown for an example electric vehicle 100 in which embodiments of the present disclosure may be used. The electric vehicle 100 is a typical electric vehicle insofar as there are numerous applications onboard that are all powered by a rechargeable power supply. Power from the rechargeable power supply is provided to these applications via one or more power distribution systems, a simplified example of which is depicted at 102. Several such power distribution systems may be present throughout the electric vehicle 100 depending on the particular implementation.

The simplified power distribution system 102 in the example of FIG. 1 includes a rechargeable power supply 104, a circuit interrupt device 106 electrically connected to the rechargeable power supply 104, and at least one load 108 electrically connected to the circuit interrupt device 106. The rechargeable power supply 104 is typically a battery pack, or sometimes “battery” for short, containing a number of rechargeable batteries. The at least one load 108 may include various equipment and systems onboard the electric vehicle 100, such as a steering system, navigation system, traction control system, braking system, and the like. The circuit interrupt device 106 is a solid-state circuit breaker 106 that uses a semiconductor switch to control current flow from the power supply 104 to the at least one load 108 and, where applicable, control current flow from the at least one load 108 back to the power supply 104.

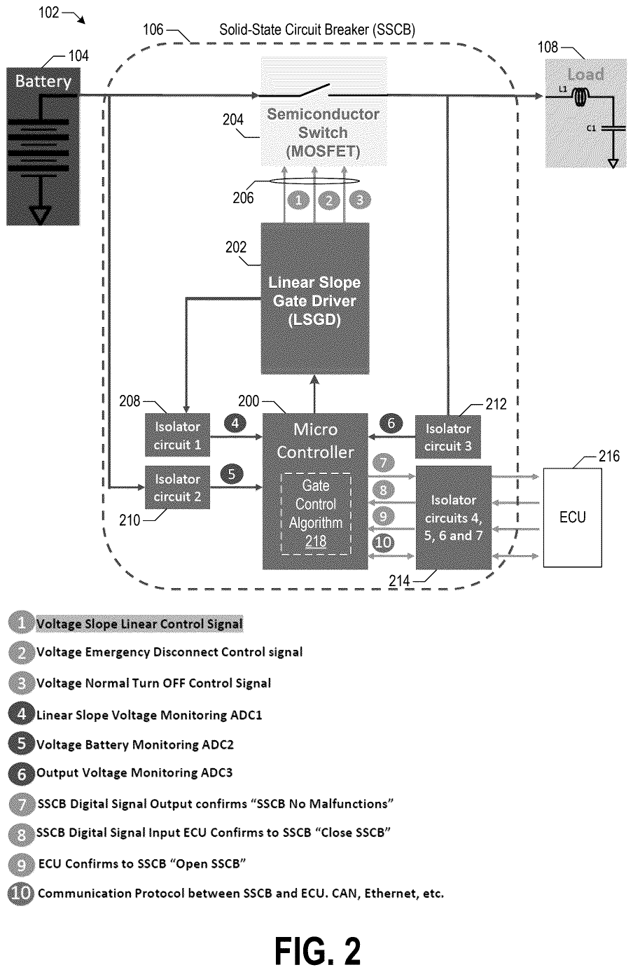

FIG. 2 shows the power distribution system 102 in more detail in the form of a block diagram. As can be seen, the solid-state circuit breaker 106 includes a microcontroller 200, a gate driver 202 in electrical communication with the microcontroller 200, and a MOSFET based semiconductor switch 204 in electrical communication with the gate driver 202. The power supply 104, as discussed above, is represented by a battery pack. Meanwhile, the at least one load 108 is represented by an LC circuit having an inductor L1 connected to a capacitor C1, as shown. It should be noted that, although various embodiments are described herein with respect to MOSFET transistors, persons skilled in the art will understand that alternative types of transistors may also be used within the scope of the disclosed embodiments, including IGBT, BJT, and any transistor where the voltage and current can be described by a line equation of the form y(t)=ax(t).

In the FIG. 2 example, the semiconductor switch 204 receives several electrical signals 206 from the gate driver 202, including a gate control signal (1), an emergency disconnect signal (2), and a normal disconnect signal (3). Although three separate electrical signals 206 are shown in the figure, it should be noted that the three signals 206 are depicted using a single connection herein for illustrative purposes. The microcontroller 200 similarly receives several electrical signals, including a gate monitoring signal (4) from the gate driver 202 via a first isolator circuit (isolator circuit 1), a battery output monitoring signal (5) from the power supply 104 via a second isolator circuit (isolator circuit 2), and a breaker output monitoring signal (6) from the circuit breaker 106 via a third isolator circuit (isolator circuit 3). The microcontroller 200 also sends one or more electrical signals confirming normal breaker operation (7) to an electronic controller unit (ECU) 216 via a fourth isolator circuit (isolator circuit 4), and receives one or more electrical signals to close the circuit breaker (8) from the ECU 216 via a fifth isolator circuit (isolator circuit 5), as well as one or more electrical signals to open the circuit breaker (9) via a sixth isolator circuit (isolator circuit 6). Electrical signals containing communication protocol information (10) can be exchanged between the microcontroller 200 and the ECU 216 via a seventh isolator circuit (isolator circuit 7).

In the above example, bringing the at least one load 108 up to an ON or operating voltage level (i.e., powering up the load) can be modeled as charging of capacitor C1. Charging capacitor C1 in current mode can be expressed by Equation (1) below, where I(t) is the load current, C is load capacitance, and Vis load voltage, which is typically the battery voltage. The traditional solution to Equation (1) requires solving a differential equation and takes the form of an exponential decay function, Ke^{at}, where K is an initial value, a is the rate of decay, and t is time.

$$I ( t ) = C \frac{d V}{dt} \qquad ( 1 )$$

An alternative approach to the traditional solution is to use a line equation for the load voltage V, the expression for which can be written as V (t)=mt, where m is the rate of change or “slope” of the load voltage and is typically given in volts/seconds, while t is time in seconds. By replacing V (t) in Equation (1) with mt, the charging equation can be rewritten as Equation (2) below:

$$I ( t ) = C \frac{d ( mt )}{dt} = Cm \frac{dt}{dt} = Cm \qquad ( 2 )$$

As Equation (2) shows, when the slope m of the load voltage V(t) is a constant value, the load current I(t) reduces to a constant value. This constant value for the load current I(t) greatly simplifies any programming and processing required to manage and control the load current compared to the traditional solution mentioned above. Users may then select a particular constant value for the load current I(t) based on their particular application, and an appropriate slope m may be derived to produce the selected load current.

Selection of the constant value for the load current I(t) may depend on an ON time of the at least one load 108, that is, the time by which the load 108 is required to be brought up to the ON voltage. The ON time for a load like the at least one load 108, where the load is represented by an LC circuit, can be determined as shown in Equation (3) below, with Δt representing the ON time.

$$Δ t = \frac{C V}{I} \qquad ( 3 )$$

Equation (3) may then be used to select an appropriate load current I(t) that satisfies a required ON time Δt. Alternatively, in some instances, the value of the load current I(t) may be a parameter that is imposed by a power distribution system like the power distribution system 102. Consider, for example, a load in which the ON voltage is 400 V, the capacitance is 550 μF, and load current is required to be 10 A. In that case, from Equation (3), the fastest ON time Δt for such a load is 22 ms (i.e., Δt=550 μF*400 V/10 A=22 ms). In either case, whether the constant load current is selected by a user or constrained by a particular application, a constant slope m needs to be derived to produce the constant load current.

As mentioned previously, the slope m can be expressed as a change in voltage over a change in time. This is shown in Equation (4) below. In the present case, the change in voltage reflects a change from an initial voltage (v₁) to an operating voltage (v₂), which is typically the battery voltage V_{battery}. The change in time reflects the time needed for the load voltage to go from the initial voltage (t₁) to an operating voltage (t₂), which is the ON time Δt mentioned above.

$$m = \frac{{v}_{2} - {v}_{1}}{{t}_{2} - {t}_{1}} = \frac{{V}_{battery}}{Δ t} \qquad ( 4 )$$

Equation (4) may then be used to calculate an appropriate slope m to reach a particular ON voltage V_{battery} within a target ON time Δt. Take the example discussed earlier where the load current is 10 A and the ON voltage is 400 V, resulting in an ON time of 22 ms. From Equation (4), the slope m required to achieve that ON time is 18181.818 volts/second (i.e., m=400 V/22 ms=18181.818 volts/second). A gate voltage signal having the above slope may then be applied to the MOSFET based semiconductor switch 204 to produce the constant load current that achieves the ON time. It has been found that using a constant or linear slope m to produce a constant load current is a particularly effective technique to control or otherwise limit the amount of inrush current that can occur when current first begins to flow.

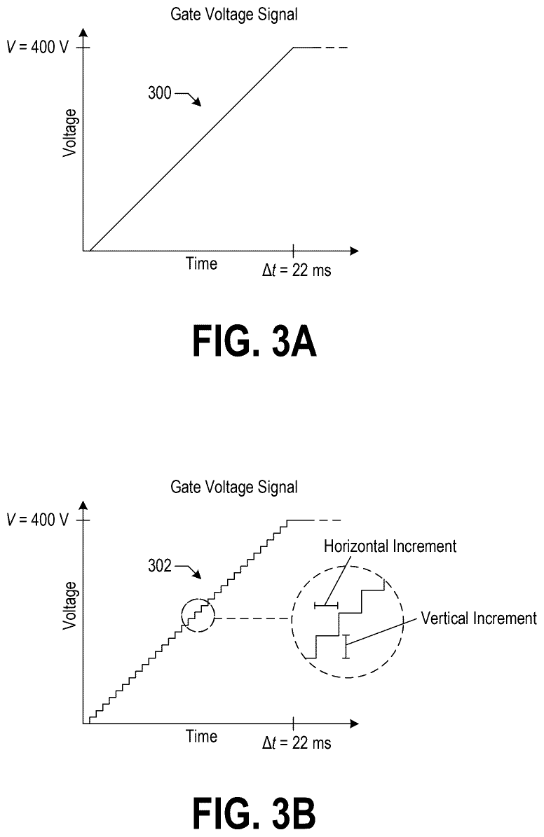

In accordance with embodiments of the present disclosure, the gate driver 202 is configured to produce a linear slope gate voltage signal having the constant slope needed for the semiconductor switch 204 to produce the constant load current. As used herein, the term “linear slope” or “constant slope” refers to a slope that is unchanging over time. In some embodiments, the slope of the gate voltage signal, along with the signal duration, timing, and other signal parameters, may be controlled by a gate control algorithm 218 in the microcontroller 200. Operation of the gate control algorithm 218 is explained with respect to FIGS. 3A-3B.

In FIGS. 3A-3B, graphs are shown illustrating a gate voltage signal having a linear slope and an approximation thereof according to embodiments of the present disclosure. In the graphs, the vertical axes represent voltage and the horizontal axes represent time. The graph in FIG. 3A depicts a conceptual gate voltage signal 300 having a slope m that is calculated to achieve an ON time of 22 ms for a load voltage of 400 V given a load current of 10 A. As can be seen, the slope of the gate voltage signal 300 is a straight line. The graph in FIG. 3B shows one way for the gate control algorithm 218 in the microcontroller 200 to reproduce a gate voltage signal like the linear slope gate voltage signal 300 of FIG. 3A, namely, by simulating or approximating the gate voltage signal.

In FIG. 3B, another gate voltage signal 302 is shown, but one that is composed of a series of identical or nearly identical discrete voltage steps. Each voltage step in the voltage signal 302 continues from where an immediately preceding step ends, so that the voltage signal 302 resembles a set of stairs. The slope of each voltage step is defined by a horizontal increment and a vertical increment for that step, which also define the overall slope of the signal 302 (i.e., m=vertical increment/horizontal increment). The slope of the voltage signal 302 may then be selected to meet a particular application requirement by selecting the size of the horizontal increment and/or the size of the vertical increment. Smaller size increments produce a smoother (finer) slope for the voltage signal 302, but require more steps and hence more voltage transitions, while larger size increments produce a rougher (coarser) slope, but require fewer steps and hence fewer voltage transitions. Note that although the vertical increments appear to occur instantaneously in FIG. 3B (i.e., with no time elapsed), in actuality some amount of time will elapse for real-world components, as discussed later herein.

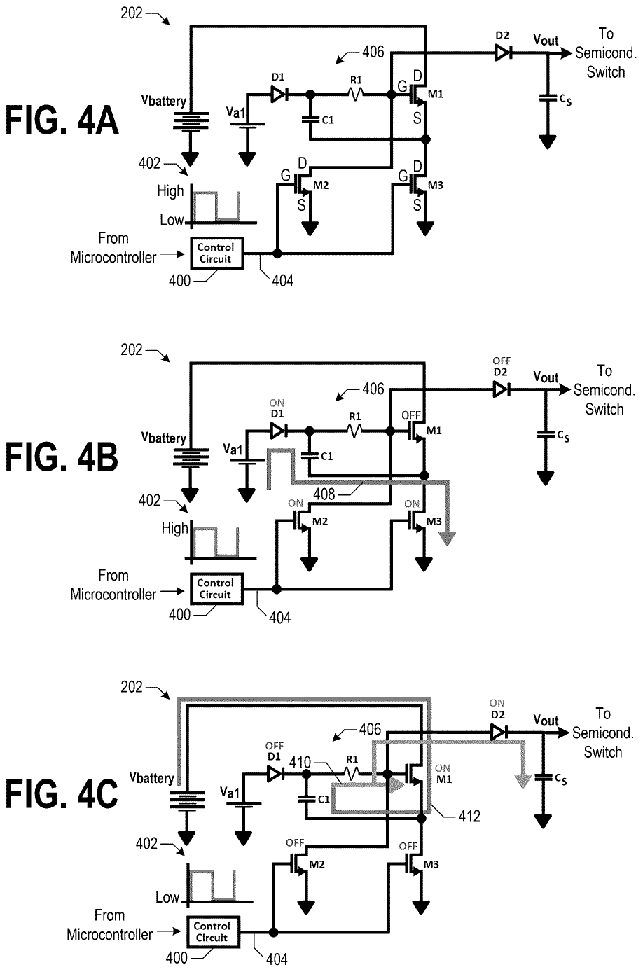

Referring next to FIGS. 4A-4C, schematic diagrams are shown for an example linear slope gate driver 202 that may be used to generate a gate voltage signal similar to the gate voltage signal 302 from FIG. 3B. The gate driver 202 in this example is configured to produce a gate voltage signal that can be applied to a gate terminal of a MOSFET based semiconductor switch like the semiconductor switch 204. Alternative gate drivers besides the one shown here may also be used for other types of semiconductor switches within the scope of the present disclosure.

As FIG. 4A shows, the gate driver 202 uses at least three NMOS transistors, M1, M2, and M3, that are connected to each other and to a control circuit 400. The control circuit 400 is configured to generate a control signal 402 going from its output 404 to the gate terminals (G) of transistors M2 and M3. The control signal 402 has a logic high level and a logic low level that are designed to turn transistors M2 and M3 on and off, respectively. The M1 drain terminal (D) is connected to a power supply V_{battery} and the M1 source terminal(S) is connected to the M3 drain terminal. A gate control network 406 composed of discrete components connects the M1 gate terminal and the M2 drain terminal. In this example, the network 406 includes a diode D1, capacitor C1, and resistor R1, all arranged as shown. Meanwhile, the M2 and M3 gate terminals are connected to the output 404 of the control circuit 400, and the M2 and M3 source terminals are connected to ground. The output voltage Vₒᵤₜ of the gate driver 202 is taken from the diode D2 cathode terminal. A storage capacitor C_{S} holds the voltage of the output voltage Vₒᵤₜ so that each Vₒᵤₜ is added to the previous Vₒᵤₜ to create a stair-like voltage signal at the gate of the semiconductor switch 204. As a result, the gate driver 202 is able to generate a gate voltage signal Vₒᵤₜ having a maximum voltage equal to the power supply V_{battery} and voltage source Val (i.e., Vₒᵤₜ=V_{battery}+Val).

It should be understood that the selection and arrangement of components shown in FIG. 4A are examples only, and alternative components and arrangements that achieve a similar result are available to persons skilled in the art. For example, bipolar transistors and even IGB transistors may be used in some embodiments instead of the NMOS transistors shown in the figure, or an integrated circuit may be used for the network 406 instead of discrete components in some embodiments. As well, rather than having a separate control circuit 400 generating a control signal 402, the control circuit 400 may be incorporated into a controller like the microcontroller 200 to generate the control signal 402 (via the gate control algorithm 218) in some embodiments.

FIGS. 4B and 4C illustrate general operation of the gate driver 202. In general, during the logic high portion of the control signal 402 (FIG. 4B), transistors M2 and M3 turn on by virtue of the logic high voltage at their gate terminals, which allows current to flow through diode D1 along the path indicated by line 408, thereby charging capacitor C1 to the level of the voltage source Vₐ₁ (i.e., V_{C1}=Vₐ₁) and also grounding the output voltage at Vₒᵤₜ (i.e., Vₒᵤₜ=0 V). Transistor M1 is off during this time due to its gate terminal being connected through M2 to ground (i.e., V_{GS1}=0 V), and therefore no charge is added to the storage capacitor C_{S}. As can be seen, by selectively setting the high portion of the control signal 402 via a controller like the microcontroller 200, a desired horizontal increment may be achieved for the steps of the gate voltage signal 302.

During the logic low portion of the control signal 402 (FIG. 4C), transistors M2 and M3 turn off by virtue of the logic low voltage at their gate terminals. Meanwhile, transistor M1 turns on by virtue of the charge previously stored in capacitor C1 flowing to the M1 gate terminal along the path indicated by line 410. This in turn allows current to flow through transistor M1 along the path indicated by line 412, thereby producing an output voltage at Vₒᵤₜ equal to the level of voltage source Vₐ₁, (i.e., Vₒᵤₜ=V_{battery}+Vₐ₁). The output voltage at Vₒᵤₜ charges the storage capacitor C_{S}, thus adding to the charge that was previously stored until reaching the maximum voltage (i.e., Vₒᵤₜ=V_{battery}+Val). Diode D2 also turns on at this time. However, to prevent the charge in capacitor C_{S} from flowing in reverse, diode D2 is turned off when M1 is turned off. As can be seen again, by selectively setting the low portion of the control signal 402 via a controller like the microcontroller 200, a desired vertical increment may be achieved for the steps of the gate voltage signal 302.

Consider an example where M1 is turned on for 10 us in the gate driver 202, and storage capacitor C_{S} will only store voltage in 2.5 V increments up to V_{battery} plus Vₐ₁. In this example, the current flowing through semiconductor switch 204 is 10 A, while the storage capacitor C_{S} is 40 μF. Thus, the vertical increment for the steps of the gate voltage signal 302 is 2.5 V. To charge the storage capacitor C_{S} to an example target voltage of 400 V, at 2.5 V per vertical increment, would require 160 steps (i.e., step number=400 V/2.5 V=160). The time needed to charge the storage capacitor C_{S} to 2.5 V at each step is: t_{S}=2.5 V*40 μF/10 A=10 μs. To satisfy an example application ON time of 22 ms (see discussion of Equation (4)) requires each step to take no longer than 137.5 μs (i.e., step time=22 ms/160 steps=137.5 μs). This means the horizontal increment for each step can last no longer than 127.5 μs in light of the 10 μs required for each vertical increment (i.e., 137.5 μs-10 μs=127.5 μs). Therefore, a controller like the microcontroller 200 should be programmed, via the voltage control algorithm 218 therein, to cause the control circuit 400 to produce a control signal 402 having about 160 consecutive cycles that each have a logic high portion lasting about 127.5 μs and a logic low portion lasting about 10 μs, within a given tolerance level (e.g., +10%).

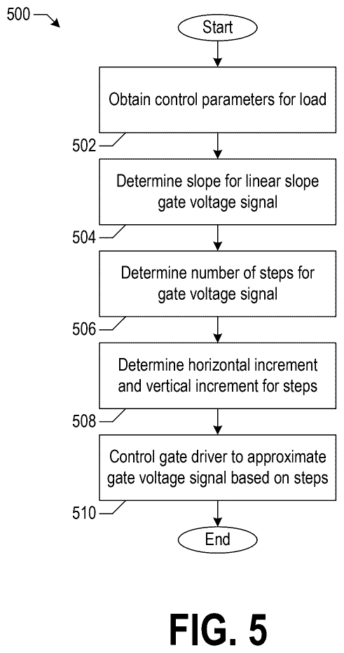

FIG. 5 is a flow diagram illustrating a method 500 that may be used by or with a controller like the microcontroller 200 and the gate control algorithm 218 therein to produce a linear slope gate voltage signal at the semiconductor switch 204, as discussed herein. The method 500 generally begins at block 502 where the microcontroller 200 obtains various control parameters for the load 108 connected to the semiconductor switch 204. These control parameters may include, for example, a constant load current, an ON voltage (i.e., battery voltage), and an ON time by which the ON voltage must be reached for the at least one load 108 connected to the switch 204. The microcontroller 200 may obtain the load control parameters from an onboard memory, a network storage unit, or the microcontroller 200 may prompt a user to enter the control parameters, for example, during an initial setup of the circuit breaker 102.

At block 504, the microcontroller 200 determines the slope needed for the gate voltage signal based on the control parameters that were obtained in the previous block. In some embodiments, the microcontroller 200 may determine the slope using Equation (4) above. At block 506, the microcontroller 200 determines the number of steps needed to produce the linear slope gate voltage signal. In some embodiments, the microcontroller 200 determines the number of steps based on the supply voltage (e.g., Vₐ₁) for the semiconductor switch 204. Thus, for example, if the supply voltage for the semiconductor switch 204 is 2.5 V and the ON voltage is 400 V, then the number of steps required is 160 steps.

At block 508, the microcontroller 200 determines a horizontal increment and a vertical increment for each step. The vertical increment for each step is usually the same as the supply voltage for the semiconductor switch (e.g., 2.5 V). In some embodiments, the microcontroller 200 determines the horizontal increment based on the ON time and the required number of steps, taking into account the transition time required for each vertical increment, as discussed above. Thus, for an ON time of, say 22 ms, each step can take no longer than 137.5 μs as discussed above, so that each horizontal increment can last no longer than 127.5 μs, assuming a vertical increment transition time of 10 μs. Thereafter, at block 510, the microcontroller 200 controls a driver circuit like the gate driver 202, either directly or indirectly through a control circuit like the control circuit 400, to generate a gate voltage signal based on, or using, the number of steps and the horizontal and vertical increments for each step.

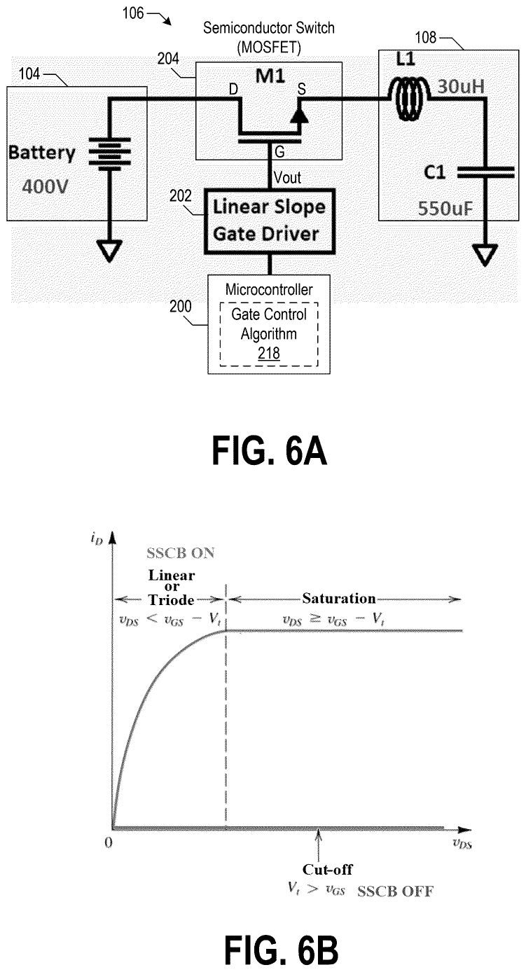

FIG. 6A is a schematic diagram showing the linear slope gate driver 202 in electrical communication with the MOSFET based semiconductor switch 204 mentioned above. The microcontroller 200 having the gate control algorithm 218 therein is configured to control the gate driver 204 to provide the gate voltage signal. In this example, the conceptual semiconductor switch 204 uses an NMOS transistor M1 to control current flow through the switch 204, with the M1 drain terminal connected to the power supply 104 and the M1 source terminal connected to the load 108. It will be appreciated that other components may also be present in the semiconductor switch 204 in addition to transistor M1 within the scope of the disclosed embodiments. It will also be appreciated that other types of transistors and combinations of transistors may be used for the semiconductor switch 204 within the scope of the disclosed embodiments. Operation of transistor M1 is discussed below with respect to FIG. 6B.

In FIG. 6B, a graph illustrates the current-voltage (I-V) characteristics of a typical MOSFET transistor like transistor M1. As can be seen, when a voltage is applied across the gate and source terminals (V_{GS}) that exceeds a threshold voltage (i.e., V_{GS}>Vₜ), also called a transistor turn-on voltage, the transistor conducts current from the drain terminal to the source terminal (I_{D})). More particularly, when the voltage across the drain and source terminals (V_{DS}) remains less than the turn-on voltage (i.e., V_{DS}≤V_{GS}−Vₜ), then the transistor is operating in a triode region and behaves essentially like a switch in an ON state and current flow through the transistor approaches a constant value for a given V_{GS}. When V_{DS} becomes equal to or greater than the turn-on voltage and V_{GS} is less than Vₜ (i.e., V_{DS}>V_{GS}−Vₜ and V_{GS}<Vₜ), then the transistor has entered a cut-off region and behaves as a switch in an OFF state. These latter regions, the saturation and cut-off regions, are where MOSFETs like transistor M1 are used in most semiconductor switches.

As discussed previously, semiconductor switches like the one depicted here have several advantages for circuit breaker applications. For example, these semiconductor switches have no moving parts that could cause an arc flash, and also open and close extremely fast compared to mechanical trip units. A controller like the microcontroller 200 can then be programmed to cause the gate driver 202 to produce a gate voltage signal 302 that approximates the straight line slope of the gate voltage signal 300. The gate voltage signal 302 may then be applied to the semiconductor switch 204 to achieve the target ON time of 22 ms for a load voltage of 400 V and load current of 10 A, within a given tolerance level (e.g., ±10%). However, it has been shown that current flowing through a MOSFET transistor like transistor M1 is susceptible to oscillations when a linear slope voltage signal like the gate voltage signal 300 is applied to the transistor. Such oscillations can interfere with operation of the loads and thus care should be taken to mitigate or eliminate the oscillations.

For an LC circuit like the load 108, oscillations can be described by Equation (5) below where ω₀ represents the resonant frequency of the oscillations. It has been shown that the oscillations can be damped by adding resistance to the LC circuit. Equation (6) below describes the damping effect that the resistance has on the circuit, with a being a damping factor and R representing the resistance of the circuit:

$${ω}_{0} = \sqrt{\frac{1}{LC}} \qquad ( 5 )$$

$$α = \frac{R}{2 L} \qquad ( 6 )$$

By setting ω₀ equal to α (i.e., ω₀=α), a value of R can be found that suppresses the oscillations without also suppressing the current, a condition called critically damped. Otherwise, if the value of R is too high (i.e., ω₀<α), then both the oscillations and the current are suppressed, a condition called overdamped that can cause the time to close the semiconductor switch 204 to be too long. Conversely, if the value of R is too low (i.e., ω₀>α), then the oscillations are not suppressed sufficiently and some oscillations remain, a condition called underdamped that can cause the time to close the semiconductor switch 204 to be too fast.

In the present example, the drain and source terminals of transistor M1 does have a small amount of resistance (R_{DS}), around 0.049 ohms according to some datasheets, when the transistor is operating in the saturation region (i.e., R_{DS_on}=0.049 ohms). This R_{DS_on} resistance is usually too small to critically damp the oscillations and therefore can be ignored for the purposes herein. A discrete damping resistor may be inserted into the load 108 between transistor M1 and inductor L1 to critically damp the oscillations in some embodiments, but it has been shown that the additional resistor can create unwanted power dissipation issues in the load 108.

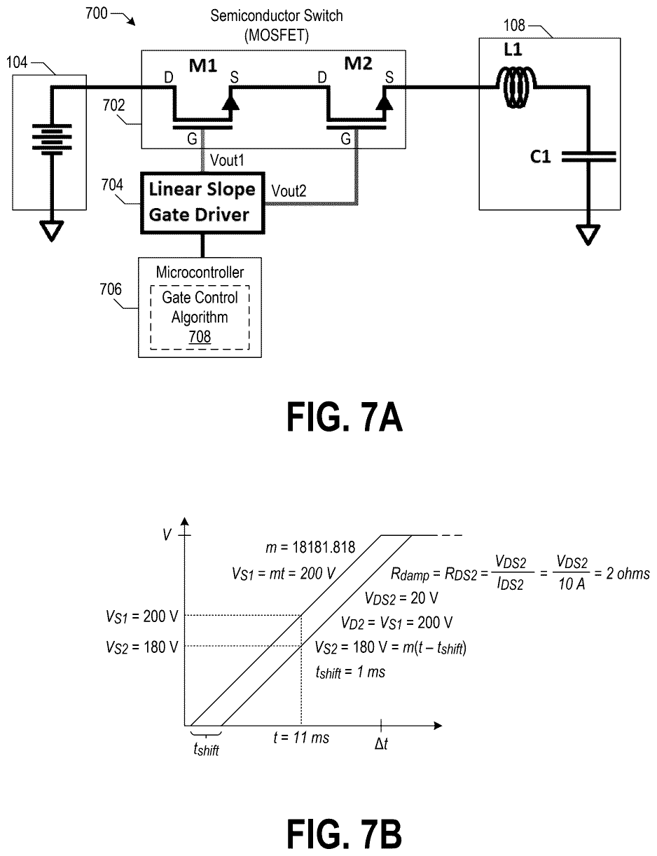

In accordance with embodiments of the disclosure, the power dissipation issue that can arise with a discrete damping resistor may be mitigated by adding a second MOSFET transistor instead to the semiconductor switch 204. The second MOSFET transistor can be operated to selectively provide a damping resistance for the semiconductor switch 204 only when needed during application of a linear slope voltage signal to the switch 204. When the damping resistance is no longer needed for the semiconductor switch 204, the second MOSFET transistor can be returned to normal operation (i.e., when R_{DS_on}=0.049 ohms). The use of the second MOSFET transistor to selectively provide a damping resistance is discussed below with respect to FIGS. 7A-7B.

In FIG. 7A, a schematic diagram is shown illustrating another solid-state circuit breaker 700 according to some embodiments. The circuit breaker 700 in this example has a semiconductor switch 702 that uses at least two transistors connected in series, and a linear slope gate driver 704 that provides a gate voltage signal to each transistor. A microcontroller 706 having a gate control algorithm 708 therein is configured to control the gate driver 704 to provide the gate voltage signals. As can be seen, the semiconductor switch 702 has at least two NMOS transistors, M1 and M2, with the M1 source terminal connected to the M2 drain terminal, the M1 drain terminal connected to the power supply 104, and the M2 source terminal connected to the load 108. The linear slope gate driver 704, meanwhile, is configured to generate a gate voltage signal for each transistor, with gate voltage signal Vₒᵤₜ₁ going to transistor M1 and gate voltage signal Vₒᵤₜ₂ going to transistor M2. The gate voltage signals Vₒᵤₜ₁ and Vₒᵤₜ₂ have the same or nearly the same linear slope and are otherwise nearly identical.

In some embodiments, Vₒᵤₜ₂ is simply a time delayed version of Vₒᵤₜ₁, and may be implemented, for example, by adding an internal time delay circuit to the gate driver 202 (see FIGS. 4A-4C), then outputting a second Vₒᵤₜ signal after the time delay circuit. It is also possible to implement the time delay using two separate gate drivers, one each for Vₒᵤₜ₁ and Vₒᵤₜ₂, with a microcontroller like the microcontroller 200 controlling both gate drivers. In either case, these gate voltage signals Vₒᵤₜ₁ and Vₒᵤₜ₂ may then be used to compel transistor M2 to temporarily behave as a damping resistor by virtue of Equation (7) below.

$${R}_{DS 2} = \frac{{V}_{DS 2}}{{I}_{DS 2}} \qquad ( 7 )$$

In Equation (7), R_{DS2} is the resistance across the M2 drain and source terminals and V_{DS2} is the voltage across the same terminals, while I_{DS2} is the current flowing through these terminals. When M2 is operating in the saturation region, R_{DS2} is largely proportional to V_{DS2} because I_{DS2} is essentially constant in this region according to its I-V curve. Thus, to produce an R_{DS2} that is sufficiently large to critically damp oscillations, V_{DS2} needs to be increased. The increase can be accomplished in accordance with the disclosed embodiments by selectively shifting a start time of the gate voltage signals Vₒᵤₜ and Vₒᵤₜ₂ by a shift time (t_{shift}) relative to one another (i.e., t_{Vout2}=t_{Vout1}+t_{shift}). This causes M2 to turn on at a later time relative to M1, which creates a voltage differential across the M2 drain and source terminals, thereby increasing V_{DS2}.

Recall from above that the gate voltage signals Vₒᵤₜ₁ and Vₒᵤₜ₂ have the same or nearly the same linear slope m. As a result, the voltages appearing at the M1 source terminal (V_{S1}) and M2 source terminal (V_{S2}) also have the same or nearly the same linear slope m. This means that V_{S1} and V_{S2} will rise evenly if Vₒᵤₜ and Vₒᵤₜ₂ start at the same time. But if a time delay is applied at the start of Vₒᵤₜ₂, then V_{S2} will not rise evenly with V_{S1}, and will instead have a different voltage from Vₒᵤₜ₁ at a given moment in time. Consequently, by controlling the linear slope gate driver 704 to shift Vₒᵤₜ₂ in time relative to Vₒᵤₜ₁, a voltage differential can be created between V_{S2} and V_{S1}. And recognizing that V_{D2} will be the same as V_{S1}, the voltage differential that was created will cause V_{DS2}, and hence R_{DS2}, to increase.

FIG. 7B is a graph showing V_{S1} and V_{S2} shifted in time, where the horizontal axis represents time and the vertical axis represents voltage. As can be seen, V_{S2} has been shifted in time by t_{shift} relative to V_{S1} by virtue of Vₒᵤₜ₂ being shifted in time by t_{shift} relative to Vₒᵤₜ₁. The line equation for V_{S1} may be written as V_{S1}=mt, while the line equation for V_{S2} may be written as V_{S2}=m (t−t_{shift}). A desired damping resistance R_{damp} may then be induced at M2 by selecting an appropriate value for t_{shift} that results in a desired voltage differential at V_{DS2}. This damping resistance may R_{damp} be maintained at M2 for as long as needed by maintaining the time shift for V_{S2} relative to V_{S1}. Once the damping resistance is no longer needed, the time shift can be terminated by reversing or otherwise removing the time shift from the gate voltage signals Vₒᵤₜ₁ and Vₒᵤₜ₂ or allowing the shift to end naturally through normal operation, thereby restoring the typically negligible drain-source resistance of M2. In some embodiments, the damping resistance is phased out or reduced to the characteristic resistance across the M2 drain and source terminals (R_{DS_ON}) when the output voltage at the semiconductor switch 204 has reach its intended maximum value (V_{battery}) and the microcontroller 200 or a similar microcontroller transitions operation of transistors M1 and M2 from the saturation region to the linear region of the I-V curve.

Take an example where the slope m is determined to be 18181.818 volts/second based on a load current of 10 A, a load voltage of 400 V, and an ON time of 22 ms. The desired damping resistance R_{damp} is 2 ohms based on Equations (5) and (6) above. From Equation (7), the desired V_{DS2} for a damping resistance of 2 ohms is 20 V (i.e., V_{DS2}=2 ohms*10 A=20 V). Thus, at a given time of, say 11 ms (t=11 ms), the voltage at the M1 source terminal is 200 V based on the V_{S1} line equation (i.e., V_{S1}=18181.818 volts/second*11 ms=200 V), while the voltage at the M2 source terminal is 180 V (i.e., V_{S2}=V_{S1}−20 V=180 V). The shift time t_{shift} needed to produce a voltage at the M2 source terminal of 180 V at a given time of 11 ms can be found using the V_{S2} line equation (i.e., V_{S2}=m (t−t_{shift})=180 V). Solving the line equation shows that V_{S2} needs to lag behind V_{S1} by 1 ms (i.e., t_{shift}=1 ms) to reach 180 V at 11 ms. Therefore, a desired damping resistance R_{damp} of 2 ohms may be induced for M2 by controlling the linear slope gate driver 704 (via the microcontroller 706 and the gate control algorithm 708 therein) to delay the M2 gate voltage signal Vₒᵤₜ₂ by 1 ms relative to the M1 gate voltage signal Vₒᵤₜ₁. Other values of damping resistance R_{damp} may of course be achieved by appropriate selection of an alternative shift time t_{shift} in a similar manner.

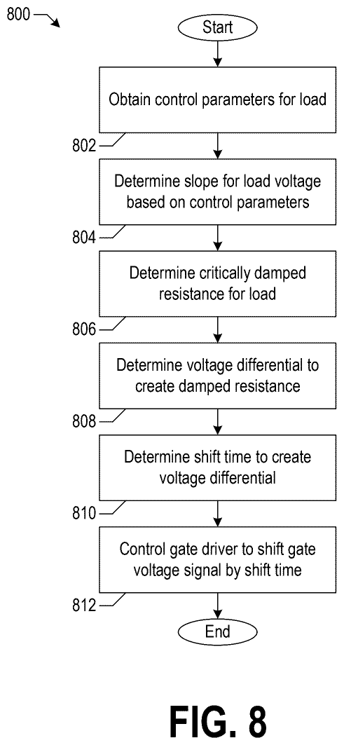

FIG. 8 is a flow diagram illustrating a method 800 that may be used by or with the microcontroller 706 (and the gate control algorithm 708 therein) to produce a desired damping resistance, as discussed earlier. The method 800 generally begins at block 802 where the microcontroller 706 obtains various control parameters for the at least one load 108 connected to the semiconductor switch 704. These load control parameters may include, for example, a constant load current, an ON voltage (i.e., battery voltage), and an ON time by which the ON voltage must be reached for the load 108. As before, the microcontroller 706 may obtain the control parameters from an onboard memory, a network storage unit, or the microcontroller 706 may prompt a user to enter the control parameters, for example, during an initial setup of the circuit breaker 700.

At block 804, the microcontroller 706 determines, retrieves from a storage location, or otherwise obtains, including simply confirming or acknowledging, a slope needed to bring the load up to an ON voltage based on the control parameters that were obtained in the previous block. In some embodiments, the microcontroller 706 may determine the slope using Equation (4) above. At block 806, the microcontroller 706 determines, retrieves from a storage location, or otherwise obtains, including simply confirming or acknowledging, a critically damped resistance needed for the load, for example, using Equations (5) and (6) above. At block 808, the microcontroller 706 determines, retrieves from a storage location, or otherwise obtains, including simply confirming or acknowledging, a voltage differential needed to create the critically damped resistance. In some embodiments, the microcontroller 706 may determine the voltage differential using Equation (7) above. At block 810, the microcontroller 706 determines, retrieves from a storage location, or otherwise obtains, including simply confirming or acknowledging, a shift time needed to create the voltage differential. In some embodiments, the microcontroller 706 may determine the shift time using the line equations for V_{S1} and V_{S2} above.

Thereafter, at block 812, the microcontroller 706 controls the gate driver 704, either directly or indirectly through a control circuit like the control circuit 400 (see FIG. 4), to generate two gate voltage signals, Vₒᵤₜ₁ and Vₒᵤₜ₂, that are shifted in time relative to one another based on, or using, the shift time determined in the previous block. The resulting voltage differential induces the critically damped resistance needed for the load.

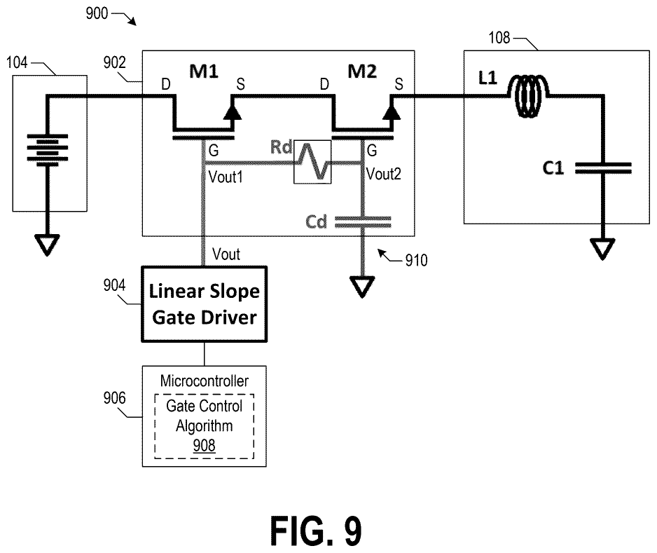

FIG. 9 is a schematic diagram illustrating yet another solid-state circuit breaker 900 according to some embodiments of the present disclosure. The circuit breaker 900 includes a semiconductor switch 902, a linear slope gate driver 904, and a microcontroller 906 having a gate control algorithm 908 therein configured to control the gate driver 904. The semiconductor switch 902 in this example is similar to the semiconductor switch 702 from FIG. 7A insofar as there are two NMOS transistors, M1 and M2, connected in series to control the flow of current through the switch 902. However, the linear slope gate driver 904 here uses an RC circuit 910 to implement the shift time t_{shift} needed to shift Vₒᵤₜ₁ and Vₒᵤₜ₂ in time relative to one another. In some embodiments, the RC circuit 910 is composed of a resistor R_{d} connected between the M1 and M2 gate terminals and a capacitor C_{d} connected between the M2 gate terminal and ground, as shown. The resistor R_{d} may be any suitable discrete resistor known to those skilled in the art, including a fixed resistor, variable resistor, voltage-controlled resistor, and other resistors having a resistance value that may be varied. In the example shown, the time shifting RC circuit 910 is implemented as part of the semiconductor switch 902, but it is certainly possible to implement the RC circuit 910 as part of the gate driver 904 instead. Operation of the RC circuit 910 is known in the art and is described by Equation (8) below.

$$τ = {R}_{d} {C}_{d} \qquad ( 8 )$$

In Equation (8), t is the time constant of the RC circuit 910 given in seconds, and is the time required for the circuit 910 to go from a logic high level to a logic low level, and vice versa. Thus, in the present example, t represents the shift time needed to delay M2 from turning on in order to produce the desired damping resistance in M2 (i.e., τ=t_{shift}). Appropriate values for resistor R_{d} and capacitor C_{d} may then be selected to achieve the needed shift time by using Equation (8). For example, given a needed shift time of, say 1 ms, a resistance of 10,000 ohms may be selected for resistor R_{d} and a capacitance of 100 nF may be selected for capacitor C_{d} (i.e., 10,000 ohms*100 nF=0.001 seconds). Alternative values for resistor R_{d} and capacitor C_{d} may of course be used to achieve the needed shift time within the scope of the present disclosure. In any case, such an RC circuit 910 passively shifts Vₒᵤₜ in time from the M1 gate terminal to the M2 gate terminal to cause M1 and M2 to turn on at different times, thereby providing a simpler solution compared to two separate gate voltage signals that are shifted in time relative to each other.

It should be noted that the arrangement of transistors M1 and M2 in the semiconductor switches 702 (FIG. 7A) and 902 (FIG. 9) discussed above produces a constant current in one direction through the switches (i.e., unidirectional current flow), which is toward the load in the depicted examples. However, embodiments of the linear slope gate driver herein can also be implemented to produce a constant current in either direction through the switches 702 and 902 (i.e., bidirectional current flow), toward the load and toward the power supply. This can be done, for example, by rearranging M1 and M2 so that their source terminals are connected to one another, with the M1 drain terminal connected to the power supply 104 and the M2 drain terminal connected to the load 108, and the M1 and M2 gate terminals connected as described above. Both topologies are effective for controlling or limiting inrush current.

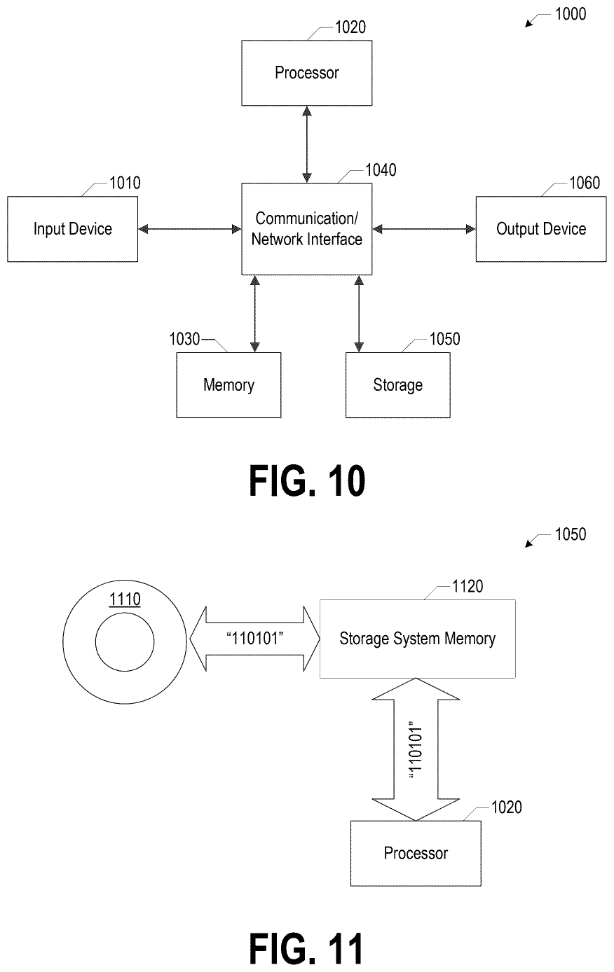

FIG. 10 illustrates an example computing system that may be used to implement various embodiments of the solid-state circuit breaker discussed in this disclosure. For example, various embodiments of the disclosure may be implemented as specialized software executing in the computing system 1000 such as that shown in FIG. 10. The system 1000 may include a processor 1020 connected to one or more memory devices 1030, such as magnetic or solid state memory, either embedded and discrete, or other memory devices for storing data. Memory 1030 is typically used for storing programs and data during operation of the system 1000. The system 1000 may also include a storage system 1050 that provides additional storage capacity. Components of system 1000 may be coupled by a communication interface 1040, which may include one or more busses (e.g., between components that are integrated within the same machine) and/or a network interface 1040 (e.g., between components that reside on separate discrete machines). The communication/network interface 1040 enables communications (e.g., data, instructions) to be exchanged between system components of system 1000 and system components of other systems on the network.

System 1000 also includes one or more input devices 1010, for example, keys, buttons, microphone, touch screen, and/or one or more output devices 1060, for example, a display screen, LEDs, and the like. In addition, system 1000 may contain one or more interfaces (not shown) that connect system 1000 to a communication network (in addition or as an alternative to the interconnection mechanism 1040).

The storage system 1050, shown in greater detail in FIG. 11, typically includes a computer readable and writeable nonvolatile recording medium 1110 in which instructions are stored that define a program to be executed by the processor 1020 or information stored on or in the medium 1110 to be processed by the program to perform one or more functions associated with embodiments described herein. To this end, the processor 1020 may be any suitable processing unit, such as a microprocessor, microcontroller, ASIC, and the like, and the medium any suitable recording medium, such as a magnetic or solid-state memory. Typically, in operation, the processor 1020 causes data to be read from the nonvolatile recording medium 1110 into storage system memory 1120 that allows for faster access to the information by the processor than does the medium 1110. This storage system memory 1120 is typically a volatile, random access memory such as a dynamic random-access memory (DRAM) or static memory (SRAM). This storage system memory 1120 may be located in storage system 1050, as shown, or in the system memory 1030. The processor 1020 generally manipulates the data within the memory system 1120 and then copies the data to the medium 1110 after processing is completed. A variety of mechanisms are known for managing data movement between the medium 1110 and the integrated circuit memory element 1120, and the disclosure is not limited thereto. The disclosure is not limited to a particular memory 1120, memory 1030 or storage system 1050.

The system 1000 may include specially programmed, special-purpose hardware, for example, an application-specific integrated circuit (ASIC). Aspects of the disclosure may be implemented in software, hardware or firmware, or any combination thereof. Further, such methods, acts, systems, system elements and components thereof may be implemented as part of the system described above or as an independent component.

Although the system 1000 is shown by way of example as one type of system upon which various aspects of the disclosure may be practiced, it should be appreciated that aspects of the disclosure are not limited to being implemented on the system as shown in FIG. 10. Various aspects of the disclosure may be practiced on one or more devices having a different architecture or components from that shown in FIG. 10. Further, where functions or processes of embodiments of the disclosure are described herein (or in the claims) as being performed on a processor or controller, such description is intended to include systems that use more than one processor or controller to perform the functions.

In the preceding, reference is made to various embodiments. However, the scope of the present disclosure is not limited to the specific described embodiments. Instead, any combination of the described features and elements, whether related to different embodiments or not, is contemplated to implement and practice contemplated embodiments. Furthermore, although embodiments may achieve advantages over other possible solutions or over the prior art, whether or not a particular advantage is achieved by a given embodiment is not limiting of the scope of the present disclosure. Thus, the preceding aspects, features, embodiments and advantages are merely illustrative and are not considered elements or limitations of the appended claims except where explicitly recited in a claim(s).

It will be appreciated that the development of an actual commercial application incorporating aspects of the disclosed embodiments will require many implementation-specific decisions to achieve a commercial embodiment. Such implementation specific decisions may include, and likely are not limited to, compliance with system related, business related, government related and other constraints, which may vary by specific implementation, location and from time to time. While a developer's efforts might be considered complex and time consuming, such efforts would nevertheless be a routine undertaking for those of skill in this art having the benefit of this disclosure.

It should also be understood that the embodiments disclosed and taught herein are susceptible to numerous and various modifications and alternative forms. Thus, the use of a singular term, such as, but not limited to, “a” and the like, is not intended as limiting of the number of items. Similarly, any relational terms, such as, but not limited to, “top,” “bottom,” “left,” “right,” “upper,” “lower,” “down,” “up,” “side,” and the like, used in the written description are for clarity in specific reference to the drawings and are not intended to limit the scope of the invention.

This disclosure is not limited in its application to the details of construction and the arrangement of components set forth in the following descriptions or illustrated by the drawings. The disclosure is capable of other embodiments and of being practiced or of being carried out in various ways. Also, the phraseology and terminology used herein is for the purpose of descriptions and should not be regarded as limiting. The use of “including,” “comprising,” “having,” “containing,” “involving,” and variations herein, are meant to be open-ended, i.e., “including but not limited to.”

The various embodiments disclosed herein may be implemented as a system, method or computer program product. Accordingly, aspects may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects may take the form of a computer program product embodied in one or more computer-readable medium(s) having computer-readable program code embodied thereon.

Any combination of one or more computer-readable medium(s) may be utilized. The computer-readable medium may be a non-transitory computer-readable medium. A non-transitory computer-readable medium may be, for example, but not limited to, an electronic, magnetic, optical, electromagnetic, infrared, or semiconductor system, apparatus, or system, or any suitable combination of the foregoing. More specific examples (a non-exhaustive list) of the non-transitory computer-readable medium can include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage system, a magnetic storage system, or any suitable combination of the foregoing. Program code embodied on a computer-readable medium may be transmitted using any appropriate medium, including but not limited to wireless, wireline, optical fiber cable, RF, etc., or any suitable combination of the foregoing.

Computer program code for carrying out operations for aspects of the present disclosure may be written in any combination of one or more programming languages. Moreover, such computer program code can execute using a single computer system or by multiple computer systems communicating with one another (e.g., using a local area network (LAN), wide area network (WAN), the Internet, etc.). While various features in the preceding are described with reference to flowchart illustrations and/or block diagrams, a person of ordinary skill in the art will understand that each block of the flowchart illustrations and/or block diagrams, as well as combinations of blocks in the flowchart illustrations and/or block diagrams, can be implemented by computer logic (e.g., computer program instructions, hardware logic, a combination of the two, etc.). Generally, computer program instructions may be provided to a processor(s) of a general-purpose computer, special-purpose computer, or other programmable data processing apparatus. Moreover, the execution of such computer program instructions using the processor(s) produces a machine that can carry out a function(s) or act(s) specified in the flowchart and/or block diagram block or blocks.

One or more portions of the computer system may be distributed across one or more computer systems coupled to a communications network. For example, as discussed above, a computer system that determines available power capacity may be located remotely from a system manager. These computer systems also may be general-purpose computer systems. For example, various aspects of the disclosure may be distributed among one or more computer systems configured to provide a service (e.g., servers) to one or more client computers, or to perform an overall task as part of a distributed system. For example, various aspects of the disclosure may be performed on a client-server or multi-tier system that includes components distributed among one or more server systems that perform various functions according to various embodiments of the disclosure. These components may be executable, intermediate (e.g., IL) or interpreted (e.g., Java) code which communicate over a communication network (e.g., the Internet) using a communication protocol (e.g., TCP/IP). For example, one or more database servers may be used to store system data, such as expected power draw, that is used in designing layouts associated with embodiments of the present disclosure.

Various embodiments of the present disclosure may be programmed using an object-oriented programming language, such as SmallTalk, Java, C++, Ada, or C#(C-Sharp). Other object-oriented programming languages may also be used. Alternatively, functional, scripting, and/or logical programming languages may be used, such as BASIC, Fortran, Cobol, TCL, Lua, Python, Rust or basic C. Various aspects of the disclosure may be implemented in a non-programmed environment (e.g., analytics platforms, or documents created in HTML, XML or other format that, when viewed in a window of a browser program render aspects of a graphical-user interface (GUI) or perform other functions). Various aspects of the disclosure may be implemented as programmed or non-programmed elements, or any combination thereof.

The flowchart and block diagrams in the Figures illustrate the architecture, functionality and/or operation of possible implementations of various embodiments of the present disclosure. In this regard, each block in the flowchart or block diagrams may represent a module, segment or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

Thus far, a number of features and advantages of embodiments of the present disclosure have been shown and described. Other possible features and advantages associated with the disclosed embodiments will be appreciated by one of ordinary skill in the art. It should also be understood that embodiments of the disclosure herein may be configured as a system, method, or combination thereof. Accordingly, embodiments of the present disclosure may be comprised of various means including hardware, software, firmware or any combination thereof.

While particular embodiments and applications of the present disclosure have been illustrated and described, it is to be understood that embodiments of the disclosure not limited to the precise construction and compositions disclosed herein and that various modifications, changes, and variations can be apparent from the foregoing descriptions without departing from the spirit and scope of the disclosure as defined in the appended claims.

I/We claim:

1. A solid-state circuit interrupt device, comprising:
a semiconductor switch operable to control current flow therethrough;
a gate driver electrically coupled to the semiconductor switch and configured to apply a gate voltage signal to the semiconductor switch; and
a microcontroller electrically coupled to the gate driver and configured to control the gate driver by:
obtaining a damping resistance for the semiconductor switch; and
controlling the gate driver to apply the gate voltage signal to the semiconductor switch to induce the damping resistance in the semiconductor switch;
wherein the damping resistance is induced in the semiconductor switch while the gate voltage signal is applied to the semiconductor switch.

2. The solid-state circuit interrupt device of claim 1, wherein the microcontroller is further configured to obtain the damping resistance by calculating a critically damped resistance value for the damping resistance.

3. The solid-state circuit interrupt device of claim 1, wherein the semiconductor switch comprises at least two transistors connected in series, and the gate voltage signal is applied to each transistor.

4. The solid-state circuit interrupt device of claim 3, wherein the gate voltage signal applied to one of the transistors is a time shifted version of the gate voltage signal applied to another one of the transistors.

5. The solid-state circuit interrupt device of claim 4, wherein the time shifted version of the gate voltage signal is shifted in time by a predefined shift time relative to the gate voltage signal that is applied to the another one of the transistors.

6. The solid-state circuit interrupt device of claim 5, wherein the predefined shift time is implemented by: the microcontroller, or a resistor-capacitor network connected to the semiconductor switch.

7. The solid-state circuit interrupt device of claim 1, wherein the damping resistance is phased out from the semiconductor switch when an output voltage at the semiconductor switch has reached a desired voltage.

8. A method of controlling current flow in a solid-state circuit interrupt device, the method comprising:
providing a semiconductor switch in the solid-state circuit interrupt device, the semiconductor switch operable to control current flow therethrough;
coupling a gate driver electrically to the semiconductor switch in the solid-state circuit interrupt device, the gate driver configured to apply a gate voltage signal to the semiconductor switch;
coupling a microcontroller electrically to the gate driver in the solid-state circuit interrupt device, the microcontroller configured to control the gate driver; and
configuring the microcontroller to:
obtain a damping resistance for the semiconductor switch; and
control the gate driver to apply the gate voltage signal to the semiconductor switch to induce the damping resistance in the semiconductor switch;
wherein the damping resistance is induced in the semiconductor switch while the gate voltage signal is applied to the semiconductor switch.

9. The method of claim 8, wherein the microcontroller is further configured to obtain the damping resistance by calculating a critically damped resistance value for the damping resistance.

10. The method of claim 8, wherein the semiconductor switch comprises at least two transistors connected in series, and the gate voltage signal is applied to each transistor.

11. The method of claim 10, wherein the gate voltage signal applied to one of the transistors is a time shifted version of the gate voltage signal applied to another one of the transistors.

12. The method of claim 11, wherein the time shifted version of the gate voltage signal is shifted in time by a predefined shift time relative to the gate voltage signal that is applied to the another one of the resistors.

13. The method of claim 12, wherein the predefined shift time is implemented by: the microcontroller, or a resistor-capacitor network connected to the semiconductor switch.

14. The method of claim 8, wherein the damping resistance is phased out from the semiconductor switch when an output voltage at the semiconductor switch has reached a desired voltage.

15. A non-transitory computer-readable medium having computer-readable instructions stored thereon for controlling current flow in a solid-state circuit interrupt device, the computer-readable instructions, when executed by a controller in the solid-state circuit interrupt device, cause the controller to:
obtain a damping resistance for a semiconductor switch of the solid-state circuit interrupt device; and
control a gate driver of the solid-state circuit interrupt device to apply a gate voltage signal to the semiconductor switch to induce the damping resistance in the semiconductor switch;
wherein the damping resistance is induced in the semiconductor switch while the gate voltage signal is applied to the semiconductor switch.

16. The method of claim 15, wherein the computer-readable instructions further cause the controller to obtain the damping resistance by calculating a critically damped resistance value for the damping resistance.

17. The computer-readable medium of claim 15, wherein the semiconductor switch comprises at least two transistors connected in series, and the gate voltage signal is applied to each transistor.

18. The computer-readable medium of claim 17, wherein the gate voltage signal applied to one of the transistors is a time shifted version of the gate voltage signal applied to another one of the transistors.

19. The computer-readable medium of claim 18, wherein the time shifted version of the gate voltage signal is shifted in time by a predefined shift time relative to the gate voltage signal that is applied to the another one of the transistors.

20. The computer-readable medium of claim 19, wherein the predefined shift time is implemented by: the microcontroller, or a resistor-capacitor network connected to the semiconductor switch.
